(19) United States
(12) Patent Application Publication
(10) Pub. No.: US 2026/0253652 A1
(43) Pub. Date: Aug. 27, 2026

(54) NON-PERIODIC READ DISTURB SCAN

(71) Applicant: Micron Technology, Inc., Boise, ID (US)

(72) Inventors: Dongxiang Liao, Cupertino, CA (US); Lei Lin, Fremont, CA (US); Guang Hu, Mountain View, CA (US); Zhengang Chen, San Jose, CA (US)

(21) Appl. No.: 19/061,726

(22) Filed: Feb. 24, 2025

(51) Int. Cl. G11C 16/34; G11C 16/26; G11C 29/52

(52) U.S. Cl. CPC G11C 16/3431; G11C 16/26; G11C 29/52

(57) ABSTRACT

This disclosure is directed to a system for performing read error handling. The system selects a set of read count (RC) thresholds using a configuration parameter that reduces periodic scan intervals. The system, in response to selecting the set of RC thresholds, generates a read disturb handling (RDH) scan configuration table based on the set of RC thresholds and performs a set of RDH scans on a portion of a memory device in response to determining that a current RC of the portion corresponds to an individual RC threshold stored in the RDH scan configuration table.

### TECHNICAL FIELD

Examples of the disclosure relate generally to memory sub-systems and, more specifically, to performing read disturb handling (RDH) operations.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 illustrates a RDH scan configuration table, in accordance with some examples.

FIG. 3 illustrates a diagram of operations performed using a RDH component, in accordance with some examples.

FIG. 4 illustrates a diagram of operations performed using a RDH component, in accordance with some examples.

FIG. 5 is a block diagram of an example computer system, according to some examples.

### DETAILED DESCRIPTION

The present disclosure is directed to a system including a memory device and a processing device, operatively coupled to the memory device, configured to perform operations that improve RDH through non-periodic read disturb (RD) scan intervals. The system does this by selecting read count (RC) thresholds using a configuration parameter and generating a RDH scan configuration table. Specifically, the disclosed processing device selects the RC thresholds using a set of configuration parameters that reduce periodic scan intervals, such as prime numbers to reduce (ideally eliminate) common factors between successive thresholds, products of two prime numbers where one prime number is fixed across the thresholds, and/or a randomizer function. When a current RC reaches one of these configured thresholds, the system performs RDH scans on the corresponding portion of the memory device. This approach enhances RDH precision by preventing skewed read patterns from evading RD detection through the use of non-periodic thresholds. The RDH scan configuration table includes multiple threshold periods corresponding to different raw bit error rate (RBER) ranges, allowing the system to adjust scan frequencies based on detected error rates. This can significantly improve overall memory sub-system performance and reliability by ensuring proper RD detection while maintaining efficient operation through reduced vulnerability to periodic read disturb workloads.

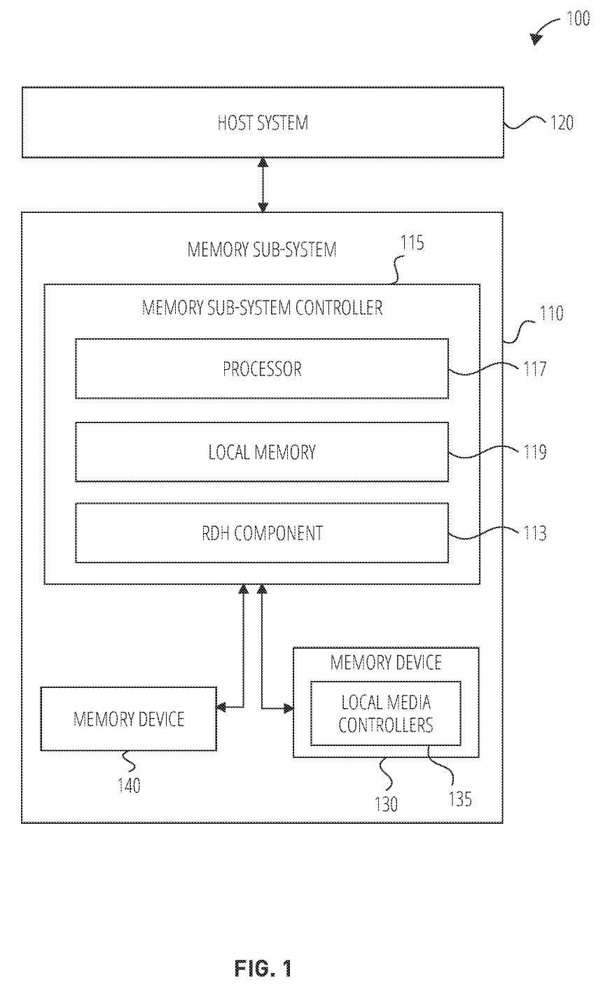

A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can send access requests to the memory sub-system, such as to store data at the memory sub-system and to read data from the memory sub-system.

The host system can send access requests (e.g., write command, read command, erase command) to the memory sub-system, such as to store data on a memory device at the memory sub-system, read data from the memory device on the memory sub-system, or write/read constructs (e.g., such as submission and completion queues) with respect to a memory device on the memory sub-system. The data to be read or written, as specified by a host request, is hereinafter referred to as “host data” or “user data.”

A host request can include logical address information (e.g., logical block address (LBA), namespace) for the host data, which is the location the host system associates with the host data and a particular zone in which to store or access the host data. The logical address information (e.g., LBA, namespace) can be part of metadata for the host data. Metadata can also include error handling data (e.g., error-correcting code (ECC) code word, parity code), data version (e.g., used to distinguish age of data written), valid bitmap (which LBAs or logical transfer units contain valid data), and so forth.

The memory sub-system can initiate media management operations, such as a write operation, on host data that is stored on a memory device. For example, firmware of the memory sub-system may re-write previously written host data from a location of a memory device to a new location as part of garbage collection (GC) management operations. The data that is re-written, for example as initiated by the firmware, is hereinafter referred to as “GC data.” Examples of system data include, but are not limited to, system tables (e.g., logical-to-physical memory address mapping table, also referred to herein as a logical-to-physical (L2P) mapping table (referred to as an L2P table), data from logging, scratch pad data, and so forth).

A memory device can be a non-volatile memory device. A non-volatile memory device is a package of one or more die. Each die can be comprised of one or more planes. For some types of non-volatile memory devices (e.g., AND-type devices), each plane is comprised of a set of physical blocks. For some memory devices, blocks are the smallest area that can be erased. Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are raw memory devices combined with a local embedded controller for memory management within the same memory device package. The memory device can be divided into one or more zones where each zone is associated with a different set of host data or user data or application.

Certain memory devices, such as NAND-type memory devices, include one or more blocks, (e.g., multiple blocks), with each of those blocks including multiple memory cells. For instance, a memory device can include multiple pages (stored across one or more word lines (WLs)), with each page including a subset of memory cells of the memory device. A threshold voltage (VT) of a memory cell (of a block) can be the voltage at which the floating gate (e.g., NAND transistor), implementing the memory cell, turns on and conducts (e.g., to a bit line coupled to the memory cell). Generally, writing data to such memory devices involves programming (by way of a program operation) the memory devices at the page level of a block, and erasing data from such memory devices involves erasing the memory devices at the block level (e.g., page level erasure of data is not possible).

In a three-dimensional (3D) NAND array, RD usually occurs during the complex interplay of different voltage levels applied during read operations. When reading data from a target WL, the memory controller applies a read voltage (Vread) to that specific WL while simultaneously applying higher pass voltages to all unselected WLs to ensure proper current sensing. The neighboring WLs immediately adjacent to the target WL receive an intermediate pass voltage (Vpass1), while all other unselected WLs receive an even higher pass voltage (Vpass) to ensure these cells remain turned on during the read operation. This voltage configuration creates two distinct types of RD effects in the memory array. During sequential reading across WLs in a block, known as equal page RD, each WL experiences uniform bias stress from the high pass voltage. This stress can inadvertently program unselected cells, with erased cells being particularly vulnerable due to their higher potential difference. When hosts repeatedly read from specific WLs, known as single page read disturb, the lateral electric field between the target WL and its neighbor WLs generates hot electrons, with this effect being most pronounced when reading lower pages due to the voltage differential between the read level and neighboring pass voltages.

To manage these RD effects, conventional systems implement firmware algorithms that monitor RCs at the VB level. When a VB reaches its RC threshold, the memory controller initiates a RD scan on WLs in a list of WLs. The list of WLs includes a predefined list of mandatory WLs, the neighbor WLs of the most recently read WL, and/or the most recently read WL itself. If this RD scan detects elevated error rates (e.g., if the RBER transgresses an RBER threshold), the memory controller refreshes the VB by relocating data from the VB to a new VB.

Conventional memory sub-systems implement RD handling using fixed periodic scan intervals based on RC thresholds and RBERs. However, this approach creates potential vulnerabilities that could be exploited through specially designed read patterns. For example, when using fixed periodic scan intervals, a skewed read pattern can be designed that aligns with the scan period to consistently evade detection. If the scan period is set to a fixed number like 110,000 reads, a workload that performs 11,000 reads (a factor of the scan period) repeatedly on specific WLs can be performed. This workload creates an uneven distribution where some WLs receive significantly more stress than others, but the periodic nature of the scan means it will always check the same WLs while missing the heavily stressed ones. The challenge is particularly evident in cases where the read pattern creates a 10:1 or higher ratio of stress between different WLs. With conventional fixed periods that have common factors (e.g., 1.1M, 660K, 220K, and 110K reads), the read pattern can be designed knowing these periods using factors, such as 11,000 or 10,000, to consistently avoid RD detection. This allows the read pattern to concentrate reads on certain WLs while ensuring the RD scan always occurs when checking less-stressed WLs.

These periodic scan vulnerabilities can be problematic because they could potentially lead to data corruption through accumulated RD effects on the heavily stressed WLs that escape detection. The fixed nature of conventional scan periods, combined with their use of numbers that have multiple common factors, creates predictable patterns that could be exploited by specially crafted test cases or malicious workloads. The technical challenge lies in maintaining effective RD detection while preventing these potential exploits.

The present disclosure addresses these inefficiencies by implementing a system that selects RC thresholds using configuration parameters that reduce periodic scan intervals. Specifically, the disclosed techniques can use any combination of processes to generate RCs for a RDH scan configuration table to eliminate or reduce common factors between successive read periods. For example, the RDH scan configuration table can be generated using any combination of prime numbers as thresholds to eliminate common factors between successive scan periods, products of two prime numbers where one prime number remains fixed across the thresholds, and/or randomizer functions. This approach prevents attack read patterns or specialized read patterns designed to exploit fixed periodic intervals since the read patterns cannot reliably predict or be aligned with the non-periodic scan schedule of the RDH scan configuration table. By maintaining these non-periodic thresholds in a RDH scan configuration table, the disclosed techniques ensure proper RD detection with minimal configuration file changes and minimal or no firmware modifications.

In some examples, a system can be implemented that includes a memory device and processing device configured to perform RDH operations. In some examples, the processing device selects RC thresholds using configuration parameters specifically designed to reduce periodic scan intervals and generates a RDH scan configuration table based on these thresholds. The processing device employs non-periodic thresholds that effectively reduce vulnerability to skewed read patterns that might attempt to evade read disturb detection. In some implementations, these RDH operations include RD handling operations performed on memory blocks or VBs, where RD scans determine whether RBER exceed specified thresholds.

In some cases, when the RBER transgresses the threshold, the processing device refreshes data in the affected portion of the memory device. The configuration parameters can be implemented in various ways. Some examples use prime numbers to eliminate common factors between successive RC thresholds, while others employ a base threshold value plus a random variation value. The processing device can also utilize configuration parameters including products of two prime numbers, where one prime number remains fixed across the RC thresholds. When performing RDH scans, the system scans neighbor WLs adjacent to the target WL that was last read.

In some implementations, the processing device determines that the configuration parameter includes a predetermined set of prime numbers. The processing device then stores these prime numbers in entries in the RDH scan configuration table, corresponding to different RBER values. These predetermined prime numbers may include co-prime numbers, and in some cases, an individual prime number in the set remains fixed. The processing device can also implement a more dynamic approach using a randomizer function and fixed percentage value. This involves obtaining current RC thresholds from the RDH scan configuration table, computing target ranges by applying fixed percentage values, and generating random values within these ranges to adjust the RC thresholds. Approaches for generating values in the RDH scan configuration table can be combined in some cases.

The RDH scan configuration table can include multiple RC threshold periods corresponding to different RBER ranges. In some implementations, this includes at least a first RC threshold corresponding to a first RBER range and a second RC threshold corresponding to a second RBER range.

These implementations can be realized in various forms, including as a system with a 3D NAND device, as instructions stored on non-transitory machine-readable storage media, or as a method performing the described operations. Regardless of the implementation approach, the core functionality remains focused on selecting RC thresholds using configuration parameters that reduce periodic scan intervals and performing RDH scans based on these thresholds.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND type flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells, such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or BSs. As used herein, a block including SLCs can be referred to as a SLC block, a block including MLCs can be referred to as a MLC block, a block including TLCs can be referred to as a TLC block, and a block including QLCs can be referred to as a QLC block.

Although non-volatile memory components such as NAND type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing GC operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), and so forth), or other suitable processor(s).

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., LBA, namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (mNAND) device. Any operation discussed as being performed by the memory sub-system controller 115 can be similarly performed by the local media controllers 135 and vice versa.

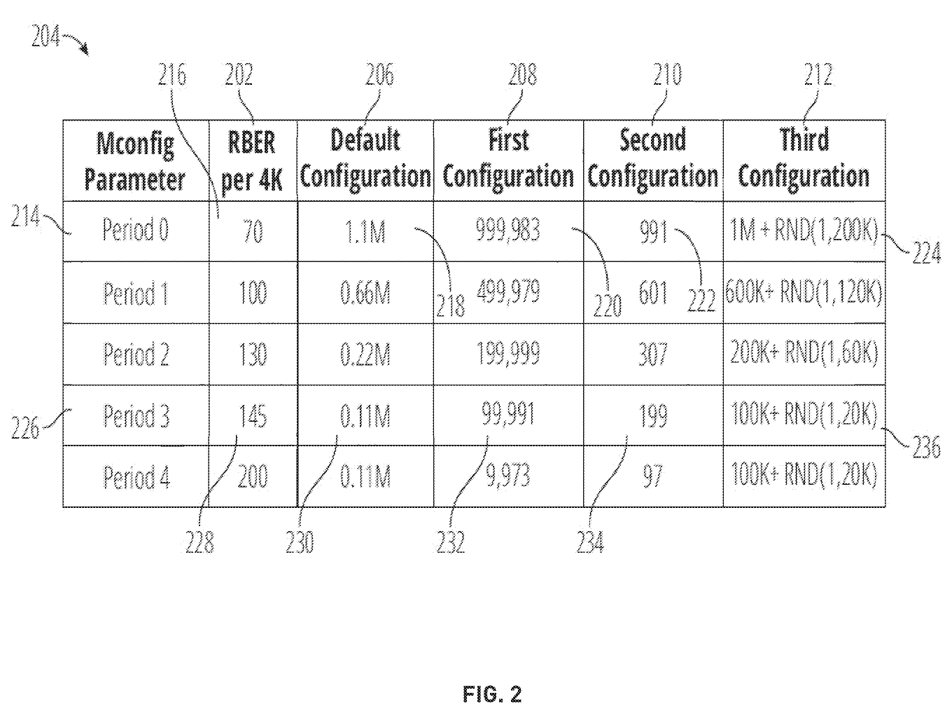

The memory sub-system controller 115 includes an RDH component 113 that works with the memory sub-system controller 115 to enable intelligent RD handling or RDH operations. The RDH component 113 monitors RC thresholds for portions of the memory device by incrementing a RC each time a portion is read. When the RC threshold is reached or exceeded, the RDH component 113 initiates RDH operations, such as by performing RD scans on the portion. During these operations, the RDH component 113 selects RC thresholds using configuration parameters specifically designed to reduce periodic scan intervals and generates a RDH scan configuration table (e.g., the RDH scan configuration table 204 shown in FIG. 2) based on these thresholds. The RDH component 113 employs non-periodic thresholds that effectively reduce vulnerability to skewed read patterns that might attempt to evade read disturb detection.

The RDH component 113 performs RD scans as part of its RDH operations. When a RC threshold associated with a current RBER of a portion of the RDH component 113 is reached for the portion of the memory device 130, the RDH component 113 initiates RD scan operations to monitor and manage potential RD effects. During RD scan operations, the RDH component 113 examines both mandatory WLs for uniform workload distribution and neighbor WLs that are adjacent to recently read target WLs. This dual scanning approach helps detect potential focused read disturbances that could occur from repeated access to specific WL. The RD scan process involves measuring RBER for the scanned portions to determine if they exceed specified RBER thresholds. If the RBER of the read WLs transgresses a threshold, the RDH component 113 can refresh the portion of the memory device 130.

Any discussion with respect to the memory device 130 can similarly be applied to the memory device 140.

FIG. 2 illustrates an RDH scan configuration table 204, in accordance with some examples. The RDH scan configuration table 204 serves as a control structure that the RDH component 113 uses to manage and trigger RDH operations, such as RD scan operations. This RDH scan configuration table 204 contains multiple configurations and their associated RC thresholds, which the RDH component 113 uses to determine when to initiate scan operations based on observed error rates. In some cases, the set of RC thresholds used by the RDH component 113 to trigger the RDH operations can be selected by the RDH component 113 by accessing configuration data stored for the memory sub-system 110 that indicates which configuration to access. In some cases, the set of RC thresholds used can be memory die specific so that different memory dies or memory devices 130 use different configurations of the RDH scan configuration table 204, or memory portion or memory block specific where different memory portions or memory blocks use different configurations of the RDH scan configuration table 204 to trigger RDH operations.

The RDH scan configuration table 204 can be organized into distinct periods, each associated with specific RBER thresholds that trigger different responses. When the RDH component 113 detects that a portion of memory device 130 has reached an RBER value, the RDH component 113 obtains the configured RC threshold associated with that RBER value or range of RBER values to trigger RDH operations.

For example, when monitoring a memory block of the memory device 130, the RDH component 113 maintains a RC that increments each time the memory block is read. Simultaneously, the RDH component 113 tracks the RBER values of the memory block. For instance, if the RBER is measured at 70 per 4K (e.g., shown in the column RBER 202), the RDH component 113 references the first period in the RDH scan configuration table 204 and uses the corresponding RC threshold of 1.1M reads under the default configuration 206 to trigger the RDH operation on the memory block. As the block experiences more reads, the RDH component 113 continues monitoring both the RC and RBER. If the RBER increases to 100 per 4K, the RDH component 113 shifts to using period 1's threshold of 0.66M reads to trigger the RDH operation. This adjustment reflects the need for more frequent scanning as error rates increase. The RDH component 113 implements different scanning frequencies based on the detected RBER ranges.

For example, if using the first configuration 208 and the memory block shows an RBER of 130 per 4K, the RDH component 113 can apply the prime number threshold of 199,999 reads. When this RC is reached, the RDH component 113 initiates a RD scan operation. For higher RBER values, such as 145 per 4K, the RDH component 113 can use even lower RC thresholds (like 99,991 reads in the first configuration 208) to trigger more frequent RD scans. This progressive reduction in RC thresholds ensures more aggressive monitoring as the memory block's error rates increase. For each configuration entry in RDH scan configuration table 204, the RDH component 113 maintains specific mappings between RBER values and corresponding RC thresholds. These mappings ensure that scan frequencies increase appropriately as error rates rise.

The default configuration 206 establishes baseline parameters starting with a 1.1M read count threshold for period 0 (RBER 70 per 4k), scaling down through subsequent periods: 0.66M for period 1 (RBER 100 per 4k), 0.22M for period 2 (RBER 130 per 4k), and 0.11M for periods 3 and 4 (RBER 145 and 200 per 4k).

For the first configuration 208, the RDH component 113 generates prime number-based thresholds to eliminate common factors between successive RC values. For example, the RDH component 113 can set 999,983 for period 0, 499,979 for period 1, 199,999 for period 2, 99,991 for period 3, and 9,973 for period 4. Specifically, when the RDH component 113 determines that a configuration specifies using first configuration 208, the RDH component 113 accesses a predetermined set of prime numbers stored in memory of the memory sub-system 110. The RDH component 113 systematically determines that the configuration parameter includes this predetermined set of prime numbers and begins the process of populating the configuration table entries of the first configuration 208.

For each period in configuration 208, the RDH component 113 stores a specific prime number from the predetermined set into the corresponding table entry. For example, the RDH component 113 stores 999,983 in the entry for period 0 (corresponding to RBER 70 per 4k), 499,979 in the entry for period 1 (corresponding to RBER 100 per 4k), 199,999 in the entry for period 2 (corresponding to RBER 130 per 4k), 99,991 in the entry for period 3 (corresponding to RBER 145 per 4k), and 9,973 in the entry for period 4 (corresponding to RBER 200 per 4k). The RDH component 113 maintains these prime numbers in the configuration table entries such that they have no common factors between successive RC thresholds. Each prime number is specifically selected and stored to correspond with particular RBER ranges, creating a progression of decreasing threshold values as RBER increases. During this storage process, the RDH component 113 associates each prime number with its corresponding RBER value in the RDH scan configuration table 204, creating entries that map specific RBERs to appropriate scan intervals. This mapping ensures that as error rates increase, the stored prime number thresholds trigger more frequent scan operations. The RDH component 113 maintains these prime numbers in the configuration table such that they have no common factors between successive RC thresholds. This characteristic is important for preventing predictable scan patterns that could potentially evade RD detection.

In some cases, the RDH component 113 determines that the configuration specifies implementation of the second configuration 210. In such cases, when implementing the second configuration 210, the RDH component 113 multiplies a fixed prime number (e.g., 973), obtained from memory, with different factors across periods (e.g., 991, 601, 307, 199, and 97) respectively. This maintains mathematical relationships while preventing predictable scan patterns.

In some cases, the RDH component 113 determines that the configuration specifies implementation of the third configuration 212. For the third configuration 212, the RDH component 113 implements a randomization approach, adding random variations to base threshold values (e.g., 1M + RND(1,200K) for period 0, 600K + RND(1,120K) for period1, 200K + RND(1,60K) for period 2, and 100K + RND(1,20K) for periods 3 and 4. For the third configuration 212, the RDH component 113 implements a randomizer function that generates variations within specified ranges while maintaining proportional relationships between periods.

When the RDH component 113 determines that the configuration specifies implementation of the third configuration 212, it employs a randomizer function to generate dynamic RC thresholds. The process begins by determining that the configuration parameter includes both a randomizer function and a fixed percentage value. For each period, the RDH component 113 first obtains the current RC threshold stored in the RDH scan configuration table of the default configuration 206. For example, for period 0, the RDH component 113 starts with a base threshold of 1M reads of the default configuration 206. The RDH component 113 then computes a target range by applying a fixed (or variable) percentage value to this base threshold. For example, starting with the base threshold of 1M (1,000,000) reads, the RDH component 113 calculates 20% of this value: 1,000,000 * 0.20 = 200,000 (200K). This establishes the maximum range for random variation.

The RDH component 113 then uses this 200K value to define the bounds for the randomizer function, allowing the randomizer function to generate random values between 1 and 200,000. For example: minimum possible threshold: 1M + 1 = 1,000,001 reads and maximum possible threshold: 1M + 200K = 1,200,000 reads.

This same percentage-based calculation or different percentages can be applied proportionally to other periods. For example, period 1 (600K base): 600,000 * 0.20 = 120,000 range; period 2 (200K base): 200,000 * 0.20 = 60,000 range; and periods 3 and 4 (100K base): 100,000 * 0.20 = 20,000 range. The RDH component 113 uses these computed ranges with the randomizer function to generate the final RC threshold values that are stored in the RDH scan configuration table entries corresponding to each period's RBER value for the third configuration 212.

Using the randomizer function, the RDH component 113 generates a random value within the computed target range. Namely, for period 0, this means generating a random value between 1 and 200K, which is then added to the base threshold of 1M. The RDH component 113 follows the same process for subsequent periods, but with proportionally scaled ranges. For period 1, the RDH component 113 uses a 600K base with random variations up to 120K (20% of 600K). Period 2 uses a 200K base with variations up to 60K, while periods 3 and 4 use 100K bases with variations up to 20K. For each period, the RDH component 113 can adjust the RC threshold using the computed random value to generate an entry in the RDH scan configuration table 204. These entries correspond to specific RBER values. For example, the randomized threshold for period 0 corresponds to an RBER of 70 per 4K, while period 1's threshold corresponds to an RBER of 100.

The randomization process continues as the RDH component 113 obtains subsequent RC thresholds from the RDH scan configuration table 204, computing new target ranges and random values for each threshold. This dynamic approach helps prevent predictable scan patterns while maintaining proportional relationships between periods.

In some examples, in response to the RDH component 113 receiving a request to read a portion of the memory device 130 (e.g., a memory block or VB), the RDH component 113 determines which period the portion falls into based on its current RBER measurements. For first period 214, the RDH component 113 specifically monitors blocks with RBER values around 70 per 4K (first RBER 216). For a second period 226, the RDH component 113 specifically monitors blocks with RBER values around 145 per 4K (e.g., second RBER 228) and associated second default RC 230.

The RDH component 113 can determine that the settings indicate that the portion of the memory device 130 is associated with the default configuration 206. In such cases, the RDH component 113 can use the default configuration 206 to trigger RDH operations for the portion being read. For example, for the default configuration 206, the RDH component 113 can use the first default RC 218. The RDH component 113 tracks the RC of the portion being read against the 1.1M threshold (e.g., the first default RC 218). When the RC reaches this first default RC 218, the RDH component 113 initiates RDH operations. As the RBER of the portion increases, the RDH component 113 uses other RC thresholds of the default configuration 206, such as second default RC 230 when the second RBER 228 is reached for the portion of the memory device 130.

In some cases, the RDH component 113 determines that the portion being read is associated with the first configuration 208. In such cases, for the first configuration 208, the RDH component 113 can use the first adjusted RC of the first configuration 220 to trigger the RDH operations when in the first period 214 rather than the first default RC 218. The first configuration 208 can specify using prime numbers where the RDH component 113 tracks the RC of the portion being read against the 999,983 threshold (e.g., the first adjusted RC of the first configuration 220). This prime number threshold eliminates common factors between successive scan intervals. As the RBER of the portion increases, the RDH component 113 uses other RC thresholds of the first configuration 208, such as second adjusted RC of the first configuration 232 when the second RBER 228 is reached for the portion of the memory device 130.

In some cases, the RDH component 113 determines that the portion being read is associated with the second configuration 210. In such cases, for the second configuration 210, the RDH component 113 can use the first adjusted RC of the second configuration 222 to trigger the RDH operations when in the first period 214 rather than the first default RC 218. As the RBER of the portion increases, the RDH component 113 uses other RC thresholds of the second configuration 210, such as second adjusted RC of the second configuration 234 when the second RBER 228 is reached for the portion of the memory device 130.

In some cases, the RDH component 113 determines that the portion being read is associated with the third configuration 212. In such cases, for the third configuration 212, the RDH component 113 can use the first adjusted RC of the third configuration 224 to trigger the RDH operations when in the first period 214 rather than the first default RC 218. The third configuration 212 can specify using a randomization approach where the RDH component 113 tracks the RC of the portion being read against a threshold generated by adding a random variation to a base value of 1M reads (e.g., the first adjusted RC of the third configuration 224 being 1M + RND(1,200K)). This randomized threshold helps prevent predictable scan patterns by introducing controlled variability.

As the RBER of the portion increases, the RDH component 113 uses other RC thresholds of the third configuration 212, such as the second adjusted RC of the third configuration 236 when the second RBER 228 is reached for the portion of the memory device 130. For this second period, the RDH component 113 generates a new randomized threshold using a 600K base value plus a random variation between 1 and 120K, maintaining the proportional relationship between periods while introducing non-deterministic elements to the scan intervals.

The RDH component 113 can implement different configurations for different portions of the memory device 130. For example, when receiving read requests for multiple portions, the RDH component 113 can determine that a first portion is associated with the first configuration 208 while a second portion is associated with the third configuration 212.

For the first portion using first configuration 208, the RDH component 113 uses the first adjusted RC of the first configuration 220 to trigger RDH operations when in the first period 214, rather than using the first default RC 218. Under this configuration, the RDH component 113 tracks the RC of the first portion against the prime number threshold of 999,983, eliminating common factors between successive scan intervals. As the RBER of this first portion increases to the second RBER 228, the RDH component 113 transitions to using the second adjusted RC of the first configuration 232 (499,979).

Simultaneously, for the second portion using third configuration 212, the RDH component 113 implements the first adjusted RC of the third configuration 224 during the first period 214. This configuration employs a randomization approach where the RDH component 113 tracks the RC of the second portion against a threshold generated by adding a random variation to a 1M base value (1M + RND(1,200K)). When this second portion reaches the second RBER 228, the RDH component 113 adjusts to use the second adjusted RC of the third configuration 236, generating a new randomized threshold using a 600K base value plus a random variation between 1 and 120K.

This flexible configuration approach allows the RDH component 113 to simultaneously manage different portions of the memory device 130 using different RC threshold strategies, such as by implementing prime number-based thresholds for some portions while using randomized thresholds for others. Each portion maintains its own read count tracking and threshold comparisons according to its assigned configuration.

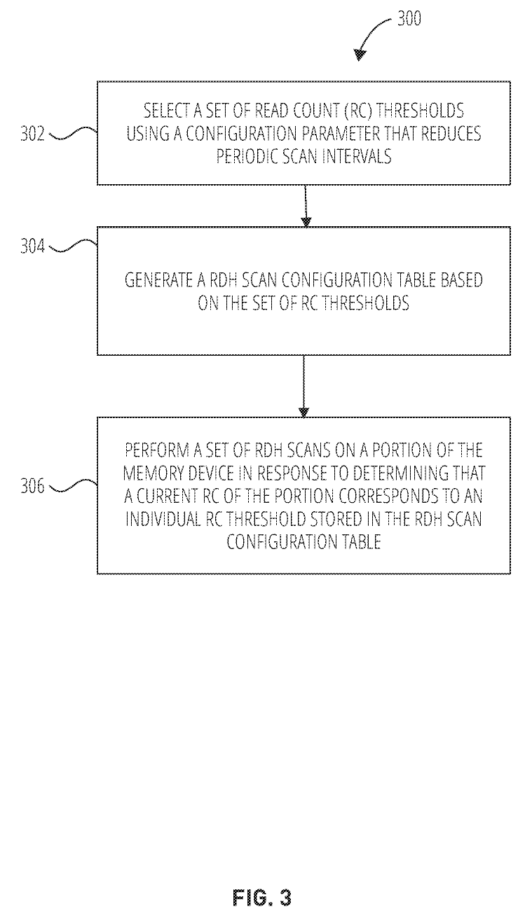

FIG. 3 illustrates a flow diagram 300 showing operations performed by the RDH component 113. The process can be implemented through various forms of processing logic, including hardware components (such as processing devices, dedicated logic circuits, programmable logic, microcode, or integrated circuits), software instructions executed on a processing device, or combinations thereof. The memory sub-system controller 115 or its subcomponents can perform these operations, with the RDH component 113 handling key aspects of the process.

The flow diagram 300 begins at operation 302, where the RDH component 113 selects a set of RC thresholds using a configuration parameter that reduces periodic scan intervals. This selection process involves accessing predetermined configuration parameters that specify either prime numbers, products of prime numbers, or randomization approaches to establish the RC thresholds.

At operation 304, the RDH component 113 generates a RDH scan configuration table based on the selected set of RC thresholds. During this operation 304, the RDH component 113 creates entries in the table that map specific RBER values to corresponding RC thresholds, establishing the framework for when scan operations should be triggered. Then, at operation 306, the RDH component 113 performs a set of RDH scans on a portion of the memory device 130 in response to determining that a current RC of the portion corresponds to an individual RC threshold stored in the RDH scan configuration table. These scans are initiated when the tracked read count reaches the configured threshold values, allowing the RDH component 113 to monitor and manage potential RD effects.

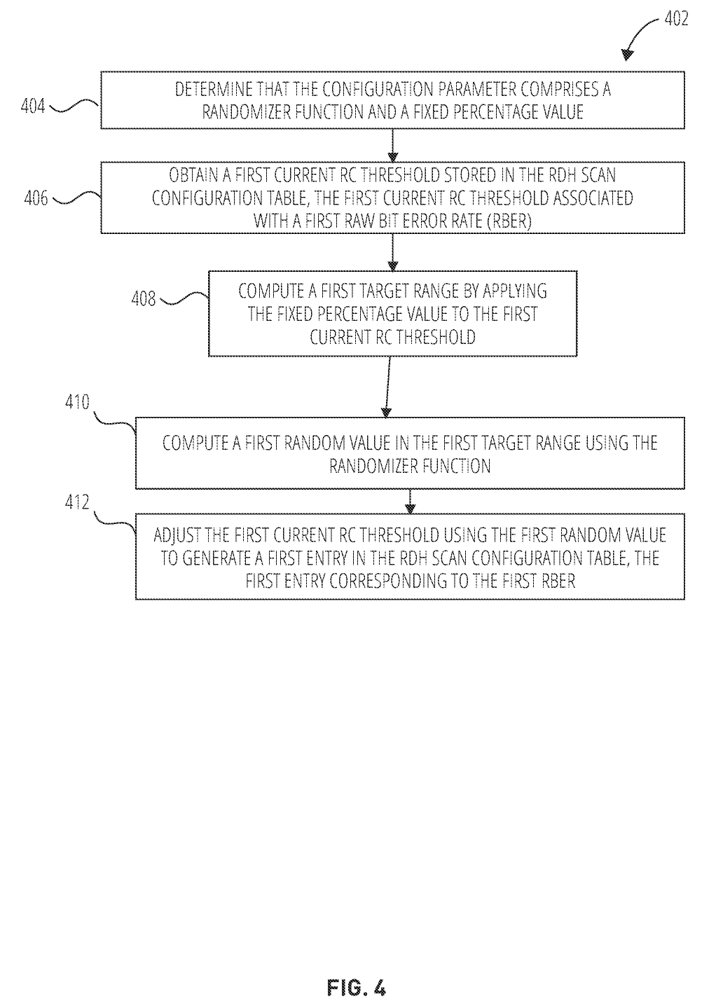

FIG. 4 illustrates a flow diagram 402 showing operations performed by the RDH component 113. The process can be implemented through various forms of processing logic, including hardware components (such as processing devices, dedicated logic circuits, programmable logic, microcode, or integrated circuits), software instructions executed on a processing device, or combinations thereof. The memory sub-system controller 115 or its subcomponents can perform these operations, with the RDH component 113 handling key aspects of the process.

The diagram 402 begins at operation 404 where the RDH component 113 determines that the configuration parameter includes a randomizer function and a fixed percentage value. This initial determination establishes the framework for generating dynamic RC thresholds. At operation 406, the RDH component 113 obtains a first current RC threshold stored in the RDH scan configuration table 204. This threshold can be associated with a first RBER, providing the base value for subsequent calculations. During operation 408, the RDH component 113 computes a first target range by applying the fixed percentage value to the first current RC threshold. For example, when working with a base threshold of 1M reads, the RDH component 113 can calculate a 20% range of 200K to establish the bounds for randomization.

At operation 410, the RDH component 113 computes a first random value in the first target range using the randomizer function. This operation generates a specific value within the computed range that will be used to adjust the threshold. Finally, at operation 412, the RDH component 113 adjusts the first current RC threshold using the first random value to generate a first entry in the RDH scan configuration table 204. This entry corresponds to the first RBER and establishes the randomized threshold that will trigger future scan operations.

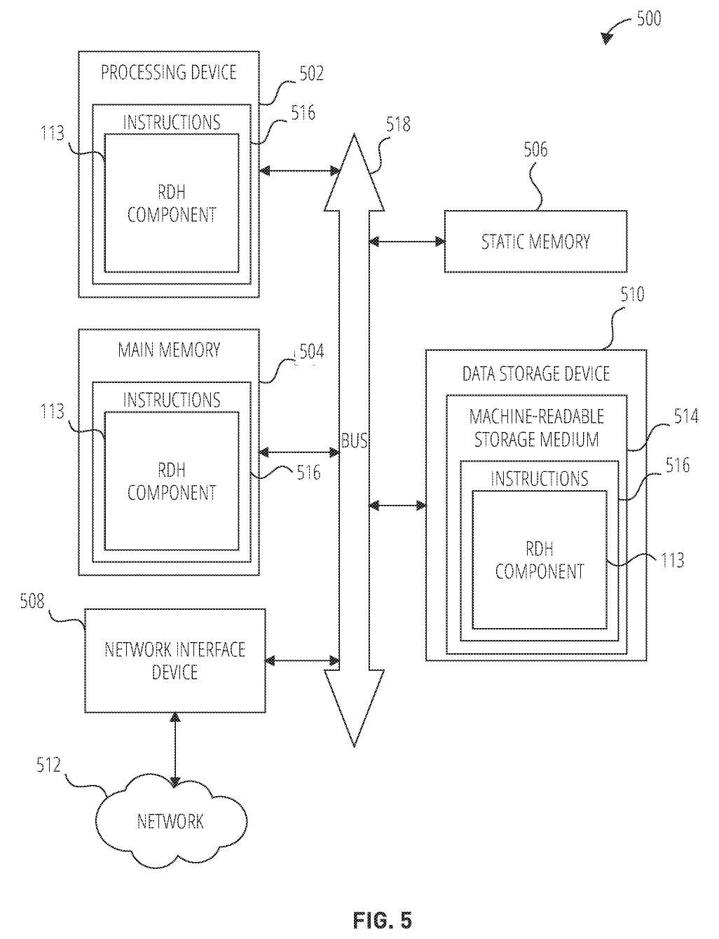

FIG. 5 illustrates an example machine in the form of a computer system 500 within which a set of instructions can be executed for causing the machine to perform any one or more of the methodologies discussed herein. In some examples, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., ROM, flash memory, DRAM such as SDRAM or Rambus DRAM (RDRAM), etc.), a static memory 506 (e.g., flash memory, static random access memory (SRAM), etc.), and a data storage device 510, which communicate with each other via a bus 518.

The processing device 502 represents one or more general-purpose processing devices such as a microprocessor, a central processing unit, or the like. More particularly, the processing device 502 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 502 can also be one or more special-purpose processing devices such as an application-specific integrated circuit (ASIC), a field programmable gate array (FPGA), a digital signal processor (DSP), a network processor, or the like. The processing device 502 is configured to execute instructions 516 for performing the operations and steps discussed herein. The computer system 500 can further include a network interface device 508 to communicate over a network 512.

The data storage device 510 can include a machine-readable storage medium 514 (also known as a computer-readable medium) on which is stored one or more sets of instructions 516 or software embodying any one or more of the methodologies or functions described herein. The instructions 516 can also reside, completely or at least partially, within the main memory 504 and/or within the processing device 502 during execution thereof by the computer system 500, the main memory 504 and the processing device 502 also constituting machine-readable storage media. The machine-readable storage medium 514, data storage device 510, and/or main memory 504 can correspond to the memory sub-system 110 of FIG. 1.

In one example, the instructions 516 include instructions to implement functionality corresponding to providing block failure protection for a zone memory sub-system as described herein (e.g., the RDH component 113 of FIG. 1). While the machine-readable storage medium 514 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1. A system comprising: a memory device; and a processing device, operatively coupled to the memory device, configured to perform operations comprising: selecting a set of RC thresholds using a configuration parameter that reduces periodic scan intervals; generating a RDH scan configuration table based on the set of RC thresholds; and performing a set of RDH scans on a portion of the memory device in response to determining that a current RC of the portion corresponds to an individual RC threshold stored in the RDH scan configuration table.

Example 2. The system of Example 1, wherein the set of RC thresholds are non-periodic thresholds that reduce vulnerability to skewed read patterns that attempt to evade read disturb detection.

Example 3. The system of any one of Examples 1-2, wherein the RDH operations comprise a RD handling (RDH) operation, and wherein the portion comprises a memory block or virtual block (VB).

Example 4. The system of Example 3, wherein performing the RDH operation comprises performing a RD scan for determining whether RBER for the portion of the memory device exceeds an RBER threshold.

Example 5. The system of Example 4, the operations comprising: refreshing data in the portion of the memory device in response to determining that the RBER transgresses the RBER threshold.

Example 6. The system of any one of Examples 1-5, wherein the configuration parameter comprises one or more prime numbers to eliminate common factors between successive RC thresholds.

Example 7. The system of any one of Examples 1-6, wherein the configuration parameter comprises a base threshold value plus a random variation value.

Example 8. The system of any one of Examples 1-7, wherein the configuration parameter comprises products of two prime numbers where one prime number is fixed across the RC thresholds.

Example 9. The system of any one of Examples 1-8, wherein performing the set of RDH scans comprises scanning neighbor WLs of a target WL, the neighbor WLs comprising one or more WLs adjacent to the target WL that was last read.

Example 10. The system of any one of Examples 1-9, the operations comprising: determining that the configuration parameter comprises a predetermined set of prime numbers; storing a first prime number of the predetermined set of prime numbers in a first entry in the RDH scan configuration table corresponding to a first raw bit error rate (RBER); and storing a second prime number of the predetermined set of prime numbers in a second entry in the RDH scan configuration table corresponding to a second RBER.

Example 11. The system of Example 10, wherein the predetermined set of prime numbers comprises co-prime numbers.

Example 12. The system of any one of Examples 10-11, wherein an individual prime number in the predetermined set of prime numbers is a fixed prime number, the operations comprising: generating the first prime number based on a product of the fixed prime number and one of the set of prime numbers; and generating the second prime number based on a product of the fixed prime number and an additional one of the set of prime numbers.

Example 13. The system of any one of Examples 1-12, the operations comprising: determining that the configuration parameter comprises a randomizer function and a fixed percentage value; obtaining a first current RC threshold stored in the RDH scan configuration table, the first current RC threshold associated with a first RBER; computing a first target range by applying the fixed percentage value to the first current RC threshold; computing a first random value in the first target range using the randomizer function; and adjusting the first current RC threshold using the first random value to generate a first entry in the RDH scan configuration table, the first entry corresponding to the first RBER.

Example 14. The operations of Example 13, the operations comprising: obtaining a second current RC threshold stored in the RDH scan configuration table, the second current RC threshold associated with a second RBER; computing a second target range by applying the fixed percentage value to the second current RC threshold; computing a second random value in the second target range using the randomizer function; and adjusting the second current RC threshold using the second random value to generate a second entry in the RDH scan configuration table, the second entry corresponding to the second RBER.

Example 15. The system of any one of Examples 1-14, wherein the RDH scan configuration table comprises a plurality of different RC threshold periods corresponding to different RBER ranges.

Example 16. The system of Example 15, wherein the RDH scan configuration table comprises: a first RC threshold corresponding to a first RBER range; and a second RC threshold corresponding to a second RBER range.

Example 17. The system of any one of Examples 1-16, wherein the memory device comprises a 3D NAND device.

Example 18. At least one non-transitory machine-readable storage medium comprising instructions that, when executed by a processing device, cause the processing device to perform operations comprising: selecting a set of RC thresholds using a configuration parameter that reduces periodic scan intervals; generating a RDH scan configuration table based on the set of RC thresholds; and performing a set of RDH scans on a portion of a memory device in response to determining that a current RC of the portion corresponds to an individual RC threshold stored in the RDH scan configuration table.

Example 19. A method comprising: selecting a set of RC thresholds using a configuration parameter that reduces periodic scan intervals; generating a RDH scan configuration table based on the set of RC thresholds; and performing a set of RDH scans on a portion of a memory device in response to determining that a current RC of the portion corresponds to an individual RC threshold stored in the RDH scan configuration table.

Example 20. The method of Example 19, wherein the set of RC thresholds are non-periodic thresholds that reduce vulnerability to skewed read patterns that attempt to evade read disturb detection.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

“Read disturb” refers to a phenomenon where repeated read operations on a specific WL in a NAND flash memory block cause unintended changes in the threshold voltages of adjacent cells on unselected WLs within the same block. This effect can potentially lead to data corruption in neighboring cells if left unmanaged, necessitating periodic data refresh or block relocation (folding) operations to maintain data integrity in NAND-based storage devices.

“Folding” refers to an operation where data from multiple partially filled pages or blocks is combined and rewritten into a single page or block. This process helps to optimize storage space utilization, reduce write amplification, and improve overall performance of the NAND storage device by consolidating fragmented data and freeing up space for new writes. Folding and “relocation” operations are used interchangeably and mean the same thing.

“High-risk WLs” or “mandatory WLs” refer to WLs within a NAND flash memory block that are more susceptible to data corruption or errors due to various factors, such as frequent read operations, physical location within the block, and/or proximity to heavily accessed areas. These WLs can require more frequent monitoring, error checking, and potential data refresh or relocation operations to maintain data integrity and overall reliability of the NAND storage device. These WLs can be predetermined and stored as part of configuration data of the memory sub-system.

“Virtual blocks (VB)” represent a logical grouping of memory cells in the memory device that is read at the same time. The VB can include multiple memory blocks that span across multiple memory dies.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

1. A system comprising:
a memory device; and
a processing device programmed to perform operations comprising:
selecting a set of read count (RC) thresholds using a configuration parameter that reduces periodic scan intervals;
in response to selecting the set of RC thresholds, generating a read disturb handling (RDH) scan configuration table based on the set of RC thresholds; and
performing a set of RDH scans on a portion of the memory device in response to determining that a current RC of the portion corresponds to an individual RC threshold stored in the RDH scan configuration table.

2. The system of claim 1, wherein the set of RC thresholds are non-periodic thresholds that reduce vulnerability to skewed read patterns that attempt to evade read disturb detection.

3. The system of claim 1, wherein the portion comprises a memory block or virtual block (VB).

4. The system of claim 3, wherein performing the RDH operation comprises performing a RD scan for determining whether raw bit error rates (RBER) for the portion of the memory device exceeds an RBER threshold.

5. The system of claim 4, the operations comprising:
refreshing data in the portion of the memory device in response to determining that the RBER transgresses the RBER threshold.

6. The system of claim 1, wherein the configuration parameter comprises one or more prime numbers to eliminate common factors between successive RC thresholds.

7. The system of claim 1, wherein the configuration parameter comprises a base threshold value plus a random variation value.

8. The system of claim 1, wherein the configuration parameter comprises products of two prime numbers where one prime number is fixed across the RC thresholds.

9. The system of claim 1, wherein performing the set of RDH scans comprises scanning neighbor word lines of a target word line, the neighbor word lines comprising one or more word lines adjacent to the target word line that was last read.

10. The system of claim 1, the operations comprising:
determining that the configuration parameter comprises a predetermined set of prime numbers;
storing a first prime number of the predetermined set of prime numbers in a first entry in the RDH scan configuration table corresponding to a first raw bit error rate (RBER); and
storing a second prime number of the predetermined set of prime numbers in a second entry in the RDH scan configuration table corresponding to a second RBER.

11. The system of claim 10, wherein the predetermined set of prime numbers comprises co-prime numbers.

12. The system of claim 10, wherein an individual prime number in the predetermined set of prime numbers is a fixed prime number, the operations comprising:
generating the first prime number based on a product of the fixed prime number and one of the set of prime numbers; and
generating the second prime number based on a product of the fixed prime number and an additional one of the set of prime numbers.

13. The system of claim 1, the operations comprising:
determining that the configuration parameter comprises a randomizer function and a fixed percentage value;
obtaining a first current RC threshold stored in the RDH scan configuration table, the first current RC threshold associated with a first raw bit error rate (RBER);
computing a first target range by applying the fixed percentage value to the first current RC threshold;
computing a first random value in the first target range using the randomizer function; and
adjusting the first current RC threshold using the first random value to generate a first entry in the RDH scan configuration table, the first entry corresponding to the first RBER.

14. The operations of claim 13, the operations comprising:
obtaining a second current RC threshold stored in the RDH scan configuration table, the second current RC threshold associated with a second RBER;
computing a second target range by applying the fixed percentage value to the second current RC threshold;
computing a second random value in the second target range using the randomizer function; and
adjusting the second current RC threshold using the second random value to generate a second entry in the RDH scan configuration table, the second entry corresponding to the second RBER.

15. The system of claim 1, wherein the RDH scan configuration table comprises a plurality of different RC threshold periods corresponding to different raw bit error rate (RBER) ranges.

16. The system of claim 15, wherein the RDH scan configuration table comprises:
a first RC threshold corresponding to a first RBER range; and
a second RC threshold corresponding to a second RBER range.

17. The system of claim 1, wherein the memory device comprises a three-dimensional (3D) NAND device.

18. At least one non-transitory machine-readable storage medium comprising instructions that, when executed by a processing device, cause the processing device to perform operations comprising:
selecting a set of read count (RC) thresholds using a configuration parameter that reduces periodic scan intervals;
in response to selecting the set of RC thresholds, generating a read disturb handling (RDH) scan configuration table based on the set of RC thresholds; and
performing a set of RDH scans on a portion of a memory device in response to determining that a current RC of the portion corresponds to an individual RC threshold stored in the RDH scan configuration table.

19. A method comprising:
selecting a set of read count (RC) thresholds using a configuration parameter that reduces periodic scan intervals;
in response to selecting the set of RC thresholds, generating a read disturb handling (RDH) scan configuration table based on the set of RC thresholds; and
performing a set of RDH scans on a portion of a memory device in response to determining that a current RC of the portion corresponds to an individual RC threshold stored in the RDH scan configuration table.

20. The method of claim 19, wherein the set of RC thresholds are non-periodic thresholds that reduce vulnerability to skewed read patterns that attempt to evade read disturb detection.
